(19) United States
(12) Patent Application Publication
(10) Pub. No.: US 2011/0228246 A1
(43) Pub. Date: Sep. 22, 2011

(54) PROJECTION OBJECTIVE FOR A MICROLITHOGRAPHIC PROJECTION EXPOSURE APPARATUS

(75) Inventors: Bernhard Kneer, Altheim (DE); Norbert Wabra, Werneck (DE); Toralf Gruner, Aalen-Hofen (DE); Alexander Epple, Aalen (DE); Susanne Beder, Aalen (DE); Wolfgang Singer, Aalen (DE)

(73) Assignee: CARL ZEISS SMT AG, Oberkochen (DE)

(21) Appl. No.: 13/115,741

(22) Filed: May 25, 2011

Related U.S. Application Data
(63) Continuation of application No. 12/194,229, filed on Aug. 19, 2008, now abandoned.
Application No. 12/194,229 is a continuation of application No. 10/597,806, filed on Aug. 8, 2006, now abandoned.
(60) Provisional application No. 60/544,967, filed on Feb. 13, 2004.
(60) Provisional application No. 60/591,775, filed on Jul. 27, 2004.
(60) Provisional application No. 60/592,208, filed on Jul. 29, 2004.

(51) Int. Cl. G03F 7/207; G02B 3/12; G02B 17/08; G03B 27/70

(52) U.S. Cl. 355/67; 359/665; 359/365; 355/77

(57) ABSTRACT

Another approach to decrease the resolution is to introduce an immersion liquid having high refractive index into the gap that remains between a final lens element on the image side of the projection objective and the photoresist or another photosensitive layer to be exposed. Projection objectives that are designed for immersion operation and are therefore also referred to as immersion objective may reach numerical apertures of more than 1, for example 1.3 or 1.4. The term “immersion liquid” shall, in the context of this application, relate also to what is commonly referred to as “solid immersion”. In the case of solid immersion, the immersion liquid is in fact a solid medium that, however, does not get in direct contact with the photoresist but is spaced apart from it by a distance that is only a fraction of the wavelength used. This ensures that the laws of geometrical optics do not apply such that no total reflection occurs.

### BACKGROUND OF THE INVENTION

1. Field of the Invention

The invention relates to microlithographic projection exposure apparatuses as are used to manufacture large-scale integrated electrical circuits and other microstructured components. More particular, the invention relates to a projection objective of such an apparatus that is designed for immersion operation.

2. Description of Related Art

Integrated electrical circuits and other microstructured components are normally produced by applying a plurality of structured layers to a suitable substrate, which may be, for example, a silicon wafer. To structure the layers, they are first covered with a photoresist that is sensitive to light of a certain wavelength range. The wafer coated in this way is then exposed in a projection exposure apparatus. In this operation, a pattern of structures contained in a mask is imaged on the photoresist with the aid of a projection objective. Since the imaging scale is generally smaller than 1, such projection objectives are frequently also referred to as reduction objectives.

After the development of the photoresist, the wafer is subjected to an etching or deposition process, as a resuit of which the uppermost layer is structured in accordance with the pattern on the mask. The photoresist still remaining is then removed from the remaining parts of the layer. This process is repeated until all the layers have been applied to the wafer.

One of the most prominent objects in the design of projection exposure apparatuses is to be able to define lithographically structures having increasingly smaller dimensions on the wafer. Small structures result in high integration densities, which generally have a favorable effect on the performance of the microstructured components produced with the aid of such apparatuses.

One of the most important parameters that determine the minimum size of the structures to be lithographically defined is the resolution of the projection objective.

Since the resolution of the projection objectives decreases as the wavelength of the projection light becomes smaller, one approach to achieve smaller resolutions is to use projection light with ever-shorter wavelengths. The shortest currently used wavelengths are in the deep ultraviolet (DUV) spectral range and are 193 nm and 157 nm.

Another approach to decrease the resolution is to introduce an immersion liquid having high refractive index into the gap that remains between a final lens element on the image side of the projection objective and the photoresist or another photosensitive layer to be exposed. Projection objectives that are designed for immersion operation and are therefore also referred to as immersion objective may reach numerical apertures of more than 1, for example 1.3 or 1.4. The term “immersion liquid” shall, in the context of this application, relate also to what is commonly referrd to as “solid immersion”. In the case of solid immersion, the immersion liquid is in fact a solid medium that, however, does not get In direct contact with the photoresist but is spaced apart from it by a distance that is only a fraction of the wavelength used. This ensures that the laws of geometrical optics do not apply such that no total reflection occurs.

Immersion operation, however, does not only allow to achieve very high numerical apertures and, consequently, a smaller resolution, but it also has a favorable effect on the depth of focus. The higher the depth of focus is, the lower are the requirements imposed on an exact positioning of the wafer in the image plane of the projection objective. Apart from that, it has been found out that immersion operation considerably relaxes certain design constraints and simplifies the correction of aberrations if the numerical aperture is not increased.

In the meantime, immersion liquids have been developed whose refractive index is significantly above that of deionized water (n_{H2O}=1.43) and that are nevertheless also highly transparent and resistant to projection light of the wavelength 193 nm. When using immersion liquids with such high refractive indices, it may happen that the refractive index of the immersion liquid is greater than the refractive index of the material of which the last optical element on the image side is composed. In conventional projection objectives having a last optical element with a plane surface on the image side, the maximum numerical aperture is restricted by the refractive index of this last optical element. If this optical element is, for example, made of quartz glass, an increase in the numerical aperture beyond the refractive index of quartz glass (n_{SiO2}=1.56) is not possible although the refractive index of the immersion liquid is even higher.

Document JP 2000-058436 A discloses a projection exposure apparatus having a projection objective can be used both in dry and in immersion operation. When switching to immersion operation, an additional lens element having a concave surface on the image side is introduced into the gap between the last optical element of the projection objective and the wafer. The interspace between the additional lens element and the wafer may be filled with an immersion liquid, for example an oil. This document does not disclose the refractive indices of the immersion liquid and the additional lens element.

### SUMMARY OF THE INVENTION

It is therefore an object of the present invention to provide an immersion projection objective in which the refractive index of the last optical element on the image side is larger is smaller than the refractive index of the immersion liquid, but having a numerical aperture that is not restricted by the refractive index of the last optical element.

This object is achieved in that, during immersion operation, the immersion liquid is convexly curved towards the object plane.

As a result of the convex curvature of the immersion liquid towards the object plane, the angles of incidence at which projection light rays impinge on the interface between an adjoining medium, e.g. the last optical element on the image side, and the immersion liquid are reduced. Thus a light ray that would be totally reflected by a flat interface can now contribute to the image, and this, in turn, allows higher numerical apertures that can also be above the refractive index of the last optical element on the image side. In this way the numerical aperture is limited only by the refractive index of the immersion liquid, but not by the refractive index of the medium that adjoins the immersion liquid on the object side.

The simplest way of achieving an immersion liquid that is convexly curved towards the object plane is to allow the immersion liquid to adjoin directly a concavely curved image-side surface of the last optical element of the projection objective. The curvature of the immersion liquid is then unalterably fixed by the curvature of this surface.

In order to prevent an undesired drainage of the immersion liquid from the cavity that is formed by the concavely curved image-side surface of the last optical element, this surface may be surrounded circumferentially by a drainage barrier. This may, for example, be a ring that is joined to the last optical element and/or a housing of the projection objective. The ring, which may be composed, for example, of a standard lens material such as quartz glass or calcium fluoride (CaF₂), but also of a ceramic or of hardened steel, is preferably provided on the inside with a coating that prevents contamination of the immersion liquid by the ring. Such a ring is also advantageous if the refractive index of the immersion liquid is equal to or smaller than the refractive index of the medium that adjoins the immersion liquid on the object side.

The image-side surface of the last optical element may be spherical. Calculations have shown that the radius of curvature may advantageously be selected to be between 0.9 times and 1.5 times and preferably 1.3 times the axial distance (i.e. vertex distance) between the this surface and the image plane. Such a configuration, which is also advantageous if the refractive index of the immersion liquid is equal to or smaller than the refractive index of the medium that adjoins the immersion liquid on the object side, has the advantage the high angles of incidence at the object side interface of the immersion liquid are avoided. Such high angles usually result in a strong sensitivity of the interface to design and manufacturing deficiencies. From this point of view, the angles of incidence should be as small as possible. This generally requires a very large curvature (i.e. a small radius of curvature) of the object-side interface of the immersion liquid.

Another way of obtaining an interface of the immersion liquid that is convexly curved toward the object plane is to introduce an intermediate liquid between the last optical element and the immersion liquid. This intermediate liquid is not miscible with the immersion liquid and forms a curved interface in an electric field during immersion operation. Such a configuration is also advantageous if the refractive index of the immersion liquid is equal to or smaller than the refractive index of the medium that adjoins the immersion liquid on the object side.

This approach makes use of an effect that is also known as “electrowetting”. If the magnitude of the electric field is altered, this is accompanied by an alteration in the curvature of the interface. This effect has hitherto been used, however, only for autofocus lenses for CCD or CMOS sensors on components that are produced by Varioptic, France.

The more the electrical conductivities of the two liquids differ from one another, the greater is the curvature of the interface. A large difference may be achieved if one of the two liquids, for example the intermediate liquid, is electrically conductive and the other liquid, for example the immersion liquid, is electrically insulating.

It is furthermore advantageous if the intermediate liquid has substantially the same density as the immersion liquid since no buoyancy forces can occur and, consequently, the shape of the interface is independent, of the position of the arrangement in space.

The refractive index of the intermediate liquid should be less than the refractive index of the immersion liquid, but it may be less or greater than the refractive index of the last optical element on the image side.

Preferably, the electric field that is necessary to form the curved interface is generated by an electrode. A symmetrical formation of the interface can be achieved, for example, by using an annular cone electrode that is disposed between the last optical element and the image plane. The curvature of the interface can be continuously varied in this way by varying a voltage applied to the electrode. This can be exploited in order to correct certain imaging properties of the projection objective.

Above it has been mentioned that it may be desirable to have a strongly curved interface between the immersion liquid and the medium adjoining to the object side, because this simplifies the correction, of imaging aberrations. However, it has also significant advantages if the curvature of this interface is small. This is because a large curvature generally leads to the formation of a cavity within the last optical element. Such a cavity has several drawbacks. For example, it favors the occurrence of undesired turbulences within the cavity if a flow of the immersion liquid has to maintained, for example for reasons of temperature stability and for purifying the liquid. Furthermore, highly refractive immersion liquids have a somewhat higher absorption than lens materials. For that reasons the maximum geometrical path lengths within the immersion liquid should be kept small. Finally, a small curvature simplifies the access to the image side surface of the last optical element for cleaning purposes.

Therefore it is generally preferred if the immersion liquid forms a convexly curved interface with a medium adjoining the immersion liquid towards the object plane such that light rays pass the interface with a maximum angle of incidence whose sine is between 0.98 and 0.5, more preferably between 0.95 and 0.85, and even more preferably between 0.94 and 0.87. The latter values correspond to angles of incidence of 60° and 70°, respectively. The angle of incidence here denotes the angle between the light ray and a surface normal at the point where the light ray impinges on the surface. These configurations are also advantageous if the refractive index of the immersion liquid is equal to, or smaller than the refractive index of the medium that adjoins the immersion liquid on the object side.

The very high numerical apertures possible according to the invention, which may be, for example, 1.6 and above, require, under some circumstances, a novel design of the projection objective. In this connection, a catadioptric projection objective comprising at least two imaging mirrors in which at least two intermediate images may be advantageous. Such a configuration is also advantageous if the refractive index of the immersion liquid is equal to or smaller than the refractive index of the medium that adjoins the immersion liquid on the object side.

### BRIEF DESCRIPTION OF THE DRAWINGS

Various features and advantages of the present invention may be more readily understood with reference to the following detailed description taken in conjunction with the accompanying drawing in which:

FIG. 1 shows a meridian section through a microlithographic projection exposure apparatus having a projection objective according to the invention in a considerably simplified view that is not to scale;

FIG. 2 shows an enlarged view of the image-side end of the projection objective shown in FIG. 1;

FIG. 3 shows an enlarged view similar to FIG. 2 for an alternative embodiment with a drainage barrier;

FIG. 4 shows the image-side end of a projection objective in accordance with another exemplary embodiment in which an intermediate liquid has been introduced between the immersion liquid and the last optical element on the image side;

FIG. 5 shows details of the geometrical conditions at the image-side end of a projection objective according to the invention;

FIG. 6 shows a meridian section through a catadioptric projection objective in accordance, with an embodiment the present invention;

FIG. 7 shows a meridian section through a catadioptric projection objective in accordance with a further embodiment the present invention;

FIG. 8 shows a meridian section through a catadioptric projection objective in accordance with another embodiment the present invention;

FIG. 9 shows a meridian section through a complete catadioptric projection objective in accordance with still another embodiment the present invention.

### DESCRIPTION OF PREFERRED EMBODIMENTS

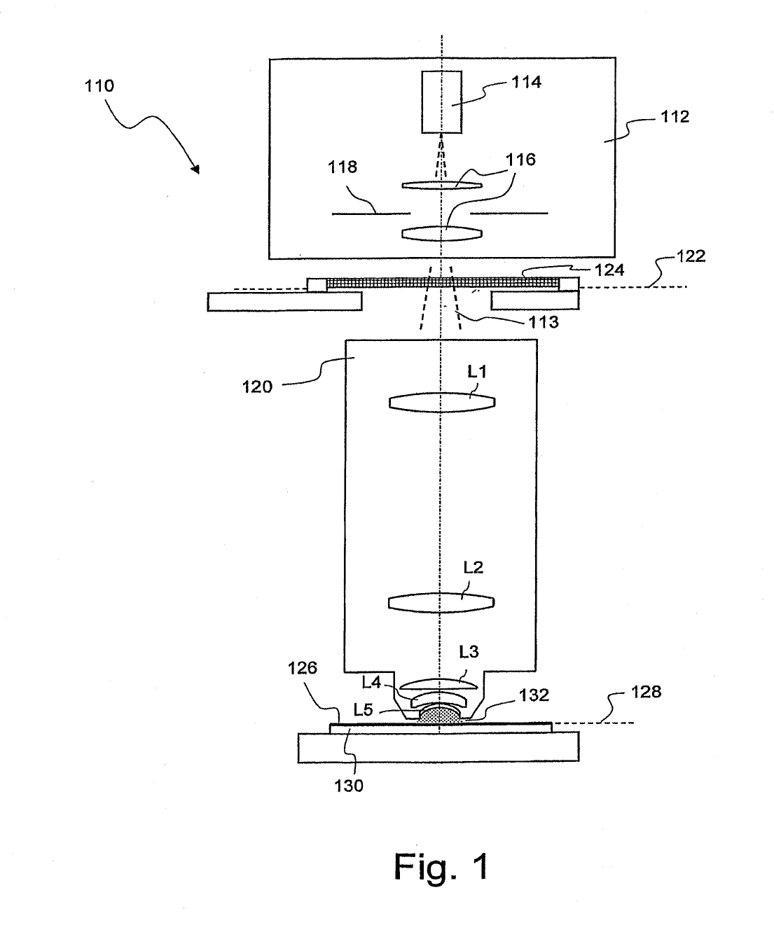

FIG. 1 shows a meridian section through a microlithographic projection exposure apparatus denoted in its entirety by 110 in a considerably simplified view that is not to scale. The projection exposure apparatus 110 comprises an illuminating system 112 for generating projection light 113 including a light source 114, illumination optics indicated by 116 and a diaphragm 118. In the exemplary embodiment shown, the projection light 113 has a wavelength of 193 nm.

The projection exposure apparatus 110 furthermore includes a projection objective 120 that comprises a multiplicity of lens elements, of which, for the sake of clarity, only a few are indicated by way of example in FIG. 1 and are denoted by L1 to L5. The projection objective 120 images a mask 124 disposed in an object plane 122 of the projection objective 120 on a reduced scale on a photosensitive layer 126. The layer 126, which may be composed of a photoresist, is disposed in an image plane 128 of the projection objective 120 and is applied to a substrate 130. The photosensitive layer 126 may itself be composed of a plurality of layers and may also comprise antireflection layers, as is known in the art as such.

An immersion liquid 134 has been introduced into a gap 132 that remains between the last lens element L5 on the image side and the photosensitive layer 126.

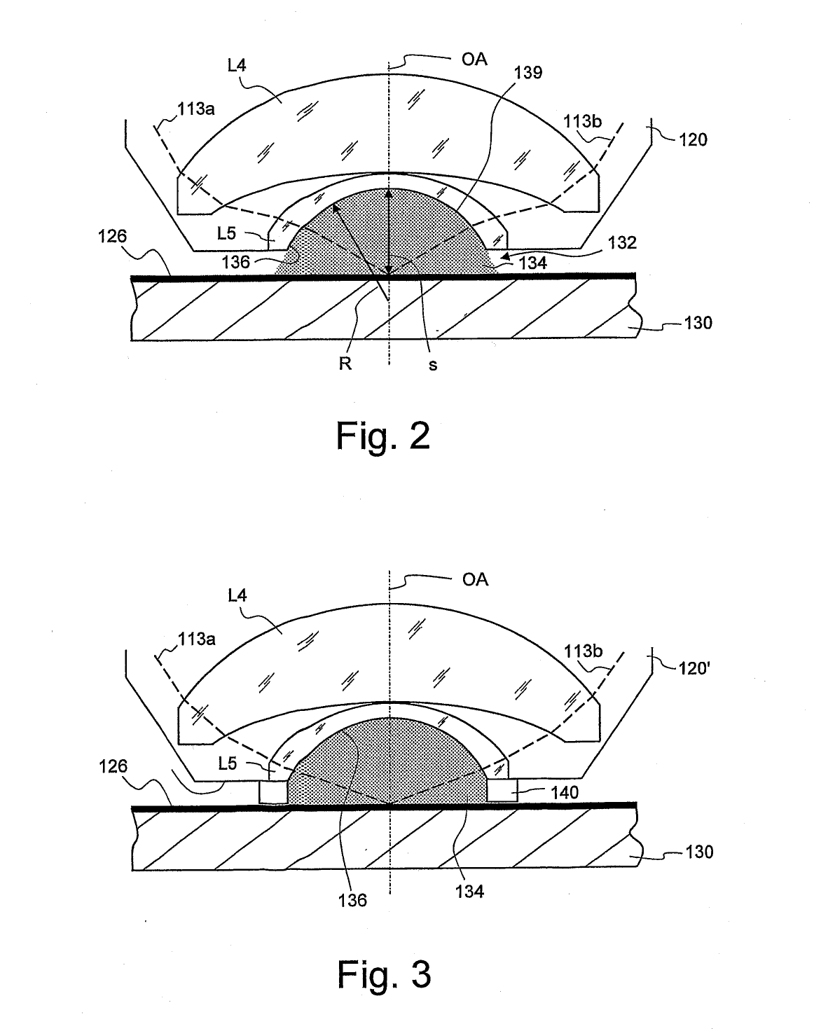

This can be seen more clearly in FIG. 2 that shows the image-side end of the projection objective 120 on an enlarged scale. The last lens element L5 on the image side has, on the image side, a surface 136 that is concavely curved. The gap 132 between the last lens element L5 on the image side and the photosensitive layer 126, which is usually flat at both ends, now transforms into a kind of cavity.

The surface 136 is approximately of spherical shell shape, the radius of curvature being denoted in FIG. 2 by R. In this arrangement, the radius of curvature R is about 1.3 times the axial distance s between, the last lens element L5 on the image side and the photosensitive layer 126.

The immersion liquid 134 has a refractive index n_{L} that is greater than the refractive index of the material n₁ of which the last lens element L5 on the image side is composed. If, for example, quartz glass or calcium fluoride is used as material, a liquid should be chosen whose refractive index n_{L} is above 1.56 or 1.5. This can be achieved, for example, by adding sulphates, alkalis such as caesium, or phosphates to water, as is described on Internet page www.eetimes.com/semi/news/OEG20040128S0017. These immersion liquids have sufficient transparency and stability even at wavelengths in the deep ultraviolet spectral range. If the projection exposure apparatus 110 is designed for longer wavelengths, for example for wavelengths in the visible spectral range, conventional immersion liquids having high refractive index, such as, for example, cedarwood oil, carbon disulphide or monobromonaphthalene may also be used as immersion liquid.

Since the immersion liquid forms, with respect to the object plane 122, a convexly curved interface 139 with the last lens element L5 on the image side, only relatively small beam incidence angles occur at said interface 139. This is shown in FIG. 2 by way of example for aperture rays 113a and 113b having a maximum aperture angles α. As a result, reflection losses at said interface are correspondingly small. Thus rays having large aperture angles with respect to an optical axis OA of the projection objective 120 may also contribute to forming an image of the mask 124, with the result that it is possible to achieve with the projection objective 120 numerical apertures that extend up to the refractive index n_{L} of the immersion liquid 134. If, on the other hand, the interface 139 were plane, as is usual in the prior art, said rays would be totally reflected at the interface between the last lens element L5 and the immersion liquid.

FIG. 3 shows a projection objective 120 in accordance with another exemplary embodiment in a view along the lines of FIG. 2. Identical parts are characterized in the figure by identical reference numerals.

The projection objective 120′ differs from the projection objective 120 shown in FIGS. 1 and 2 only in that a ring 140 is tightly joined to the last lens element L5 and a housing 141 of the projection objective 120. The ring 140 functions as a drainage barrier for the immersion liquid 134. Such a drainage barrier may be particularly advantageous if the surface 136 of the last lens element L5 on the image side is strongly curved since then the gap 132 has a large maximum extension along the optical axis OA. Accordingly, the hydrostatic pressure of the immersion liquid 134 is relatively high. Without a drainage barrier, said pressure may ultimately have the result that the immersion liquid 134 is forced out of the cavity into the surrounding gap 132 between the projection objective 120 and the photosensitive layer 126 so that a surrounding gas may enter the cavity.

The ring 140 may be composed, for example, of a standard lens material such as quartz glass or calcium chloride, but also of other materials, such as Invar™ nickel alloy, stainless steel or (glass) ceramic.

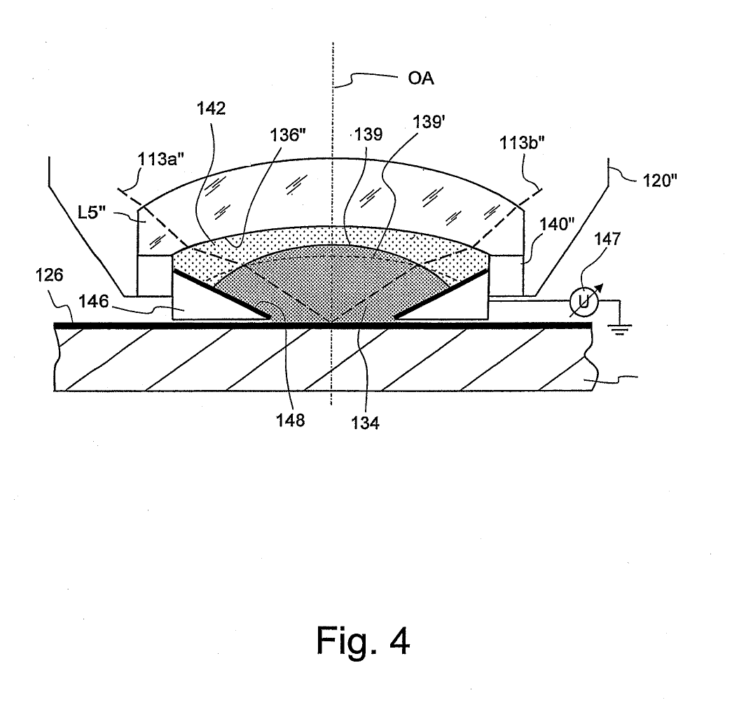

FIG. 4 shows an image-side end of a projection objective 120″ in accordance with a further exemplary embodiment in which a curvature of the immersion liquid 134 is achieved in another way.

In the projection objective 120″, the immersion liquid 134 does not directly adjoin a last lens element L5″ on the image side. Instead, a further liquid, which is referred to in the following as intermediate liquid 142, is situated between the last lens element L5″ on the image side and the immersion liquid 134. The intermediate liquid 142 is, in the embodiment shown, water to which ions have been added. Due to the ions the water becomes electrically conductive. The immersion liquid 134, which also in this case has a greater refractive index than the last lens element L5″, is electrically insulating. For wavelengths of the projection light that are in the visible spectral range, the oils and naphthalenes already mentioned above are, for example, suitable as immersion liquid 134.

The intermediate liquid 142 completely fills the space that remains between an image-side surface 136″ of the last lens element L5″ on the image side and the immersion liquid 134. The surface 136″ is convexly curved in the exemplary embodiment shown, but the latter may also be a plane surface. Adjacent to a ring 140″ that, as in the exemplary embodiment described above, has the function of a drainage barrier, a likewise annular conical electrode 146 is provided that is connected to a controllable voltage source 147. Applied to the conical electrode 146 is an insulator layer 148 that, together with the photosensitive layer 126, ensures continuous insulation of the immersion liquid 134 with respect to the image plane. The voltage source 147 generates an alternating voltage whose frequency is between 100 kHz and 500 kHz. The voltage applied to the conical electrode 146 is in the order of magnitude of about 40 V.

When the alternating voltage is applied to the conical electrode 146, the electrowetting effect known as such has the result that the interface 139 between the immersion liquid 134 and the intermediate liquid 142 convexly curves towards the object plane 122. The cause of this curvature is capillary forces that, together with the unalterability of the total volume and the tendency to the formation of a minimum surface, generate, to a good approximation, a spherical interface 139 if a sufficiently high alternating voltage is applied to electrode 146.

If the alternating voltage is now reduced, the curvature of the interface 139 decreases. In FIG. 4 this is indicated by an interface 139′ shown as a broken line. The refractive index of the liquid lens formed by the immersion liquid 134 can consequently be continuously varied in a simple way, namely by altering the electrical alternating voltage applied to the conical electrode 146. For the sake of completeness, it may also be mentioned at this point that the curvature of the interface 139 does not necessarily require an alternating voltage, but may also be achieved with a direct voltage.

Also in this embodiment, the interface of the immersion liquid 134 that is convexly curved towards the object plane 122 has the effect that a numerical aperture can be achieved that is limited not by the refractive index of the last lens element L5″ but only by the refractive index of the immersion liquid 134.

The continuous variability of the refractive power of the liquid lens formed by the immersion liquid 134 can advantageously also be used at other locations in the projection objective. Advantageously, such a liquid lens can be used at positions inside the projection objective that are exposed to particularly high light intensities. Degradation phenomena, such as occur in the case of conventional solid lenses, can be suppressed in this way or at least be repaired by simply replacing the immersion liquid. Incidentally, corresponding remarks also apply to the embodiments shown in FIGS. 2 and 3.

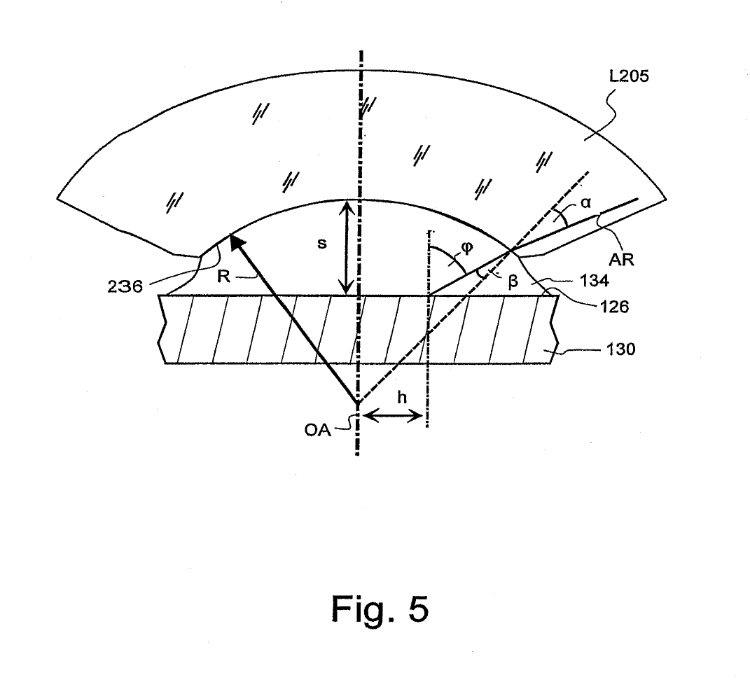

FIG. 5 shows an image-side end of a projection objective according to a still further exemplary embodiment. Here the last lens element L205 has a spherical surface 236 facing towards the image plane that has a smaller concave curvature, i.e. a larger'radius R, than the lens element L5 in the embodiments shown in FIGS. 2 and 3. In the following the geometrical conditions at the interface between the last lens element L205 and the immersion liquid 134 will be discussed in further detail.

Reference numeral AR denotes an aperture ray having a maximum aperture angle φ. The aperture ray AR impinges on the photosensitive layer 126 at a peripheral point of the image field at a height h with respect to the optical axis OA. The aperture ray AR has an angle of incidence α and an angle of refraction β at the interface between the last lens element L205 and the immersion liquid 134. The distance between the vertex of the last surface 236 of the lens element L205 and the image plane in which the photosensitive layer 126 is positioned is denoted by s.

Projection objectives are basically characterized by two quantities, namely the image-side numerical aperture

NA=n·sin(φ)

and the quantity 2 h, i.e. the diameter of a circle around the optical axis OA on which an image can be formed.

From the image-side numerical aperture NA certain geometrical properties can be derived which ensure that the light can propagate through the last lens element and immersion liquid without being reflected at the interfaces. However, the design requirements applied to the last lens element are, in practice, somewhat stricter than those that can be derived solely from the image-side numerical aperture. For example, the angle of incidence α should not exceed a certain value that is, for example, about 75°, and more preferably 70°. This is because experience shows that projection objectives having larger angles of incidence α require very complex measures to achieve a good aberration correction and a reduced sensitivity to manufacturing tolerances and changing environmental conditions.

At present projection objectives for dry operation achieve an image-side NA close to about 0.95. This means that the numerical aperture NA does not exceed 95% of the refractive index of the medium (usually a gas or a mixture of gases such as air) that immediately precedes the image plane. In such dry projection objectives the maximum angles of incidence are in the order of about 70°, in particular at the last surfaces close to the image plane but also at other surfaces of lens elements.

Since these considerations also apply to immersion objectives, the angles of incidence should be kept below these values. From geometrical considerations it becomes clear that the stronger the curvature of the surface 236 is, the smaller are the angles of incidence. Thus a strong curvature ensures that the angles of incidence do not go beyond these values.

The surface 236 of the lens element L205 should, on the other hand, not be too severely curved. This is due to the fact that a too severely curvature may result in increased problems with respect to flow mechanics, contamination and temperature sensitivity of the immersion liquid 134. For example, it may be difficult to achieve a homogenous and constant temperature of the immersion liquid 134, and, the immersion liquid 134 may be enclosed in such a way within a strongly convex cavity that replacing the immersion liquid, for example for purging reasons, becomes a very complex task.

It has been found out that a good compromise is achieved if the following condition holds for the maximum angle of incidence α:

0.95>sin(α)>0.85.

In the following a formula is derived that specifies a suitable curvature ρ as a function of NA=n.sin(φ), distance s, image height h and the refractive indices n′, n of the last lens element L205 and the immersion liquid 134, respectively, so that the sine of the angle of incidence α does not exceed a certain advantageous and practicable value. Such a value was found to be sin(α)<κ, where κ=0.95. Using the law of refraction, it follows that

$$\vert \frac{n}{{n}^{′}} sin ( β ) \vert > κ$$

According to simple geometrical considerations, it can be deduced therefrom that

$$\vert \frac{n}{{n}^{′}} ( sp - 1 ) sin ( ϕ ) \vert > κ$$

$$Thus$$

$$ρ > \frac{( 1 - \frac{{n}^{′} \cdot κ}{NA} )}{s}$$

is the condition for minimum surface curvature. For the radius R=1/ρ this gives

$$R > \frac{s}{( 1 - \frac{{n}^{′} \cdot κ}{NA} )} .$$

For an exemplary numerical aperture NA=1.5 and SiO₂ as material for the last lens element L205 with n′=1.56, this results in

R>m·s

with m≈83. For s=2 mm, this leads to a radius R of about 167 mm for the maximum radius of curvature.

If, in addition, the aperture rays of the outermost image point are taken into account in the case of a finite image field, it is sufficient for this purpose to substitute the distance s by s′ according to

$${s}^{′} = s \frac{h}{tan ϕ}$$

in the above formulae. For a maximum field height h, it then follows for the minimum curvature ρ

$$ρ > ( 1 - \frac{{n}^{′} \cdot κ}{NA} ) / ( s - \frac{h}{tan ϕ} )$$

If one starts with a projection objective having the above mentioned parameters, i.e. NA=1.5 and n′=1.56, and if one further assumes that the maximum field height h is 15 mm, the maximum radius of curvature R should be below m=83 times (s−5.57 mm). For s=8 mm, this results in a maximum radius of curvature R of approximately 200 mm, and for s=10 mm R is approximately 375 mm.

If, for example, κ is selected to be'0.95 and an immersion liquid with a refractive index of n=1.43 is used, a numerical aperture NA=1.35 may be realized with a last lens element L205 that is made of SiO₂ and which has a distance s=2 mm to the image plane and has a maximum radius of curvature below approximately 80 mm. The aforementioned detrimental effects that occur in the case of large curvatures can be minimized if the maximum radius of the surface is not only below the given values, but at least substantially identical to these values.

Apart from the fact that the maximum angle of incidence should not exceed certain upper and lower limits as is explained above, it should be ensured that the light rays rather quickly converge if one looks from a point on the image plane towards the object plane. Otherwise optical elements with very large diameters would be required.

This qualitative design rule can be mathematically expressed in the following way: If k, l, m are the three direction cosines of an aperture ray and n is the refractive within a medium with k²+l²+m²=n², there should be no volume in the objective (particularly in the vicinity of the image plane) in which (k²+l²)/n²>K₀. The limit K₀ may be selected to be K₀=0.95 or even better K₀=0.85.

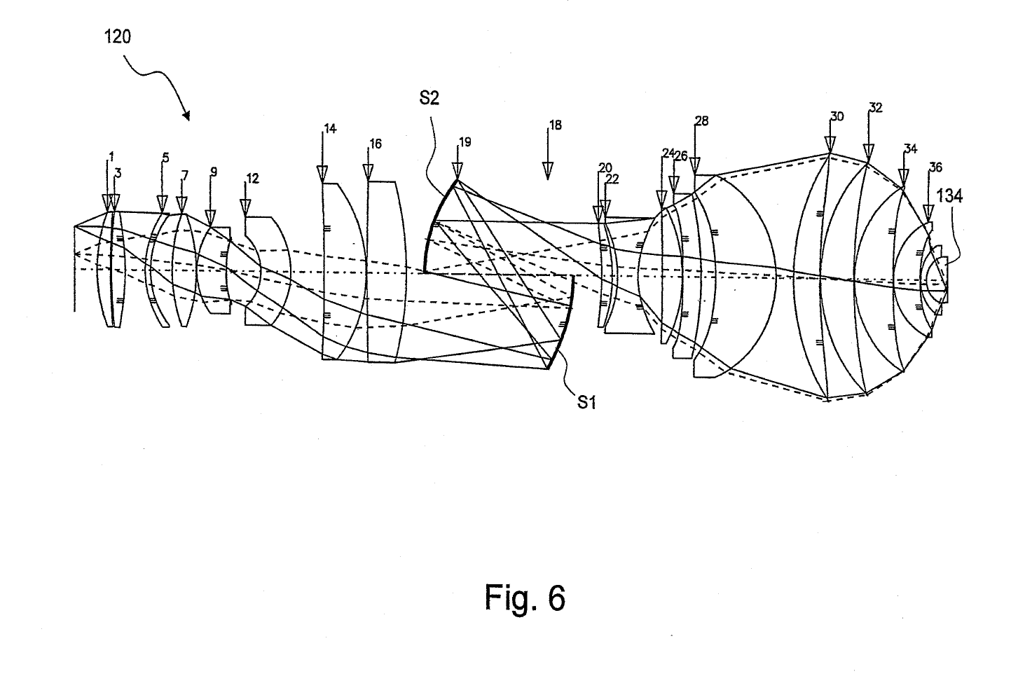

FIG. 6 shows a meridian section through a first exemplary embodiment of the projection objective 120 shown in FIGS. 1 and 2. The design data of the projection objective are listed in Table 1; radii and thicknesses are specified in millimeters. The numerals above the projection objective point to selected surfaces of optical elements. Surfaces that are characterized by groups of short bars are aspherically curved. The curvature of said surfaces is described by the aspherical formula below:

$$z = \frac{c {h}^{2}}{1 + \sqrt{1 - ( 1 + k ) {c}^{2} {h}^{2}}} + A {h}^{4} + B {h}^{6} + C {h}^{8} + D {h}^{10} + E {h}^{12} + F {h}^{14}$$

In this equation, z is the saggita of the respective surface parallel to the optical axis, h is the radial distance from the optical axis, c=1/R is the curvature at the vertex of the respective surface where R is the radius of curvature, k is the conical constant and A, B, C, D, E and F are the aspherical constants listed in Table 2. In the exemplary embodiment, the spherical constant k equals zero.

The projection objective 120 contains two aspherical mirrors S1 and S2 between which two (not optimally corrected) intermediate images are produced. The projection objective 120 is designed for a wavelength of 193 nm and a refractive index n_{L} of the immersion liquid of 1.60. The linear magnification of the projection objective 120 is β=−0.25 and the numerical aperture is NA=1.4. Some additional improvements, however, make it possible to achieve without difficulty also a numerical aperture NA that just reaches the refractive index of the immersion medium and is, consequently, only slightly less than 1.6.

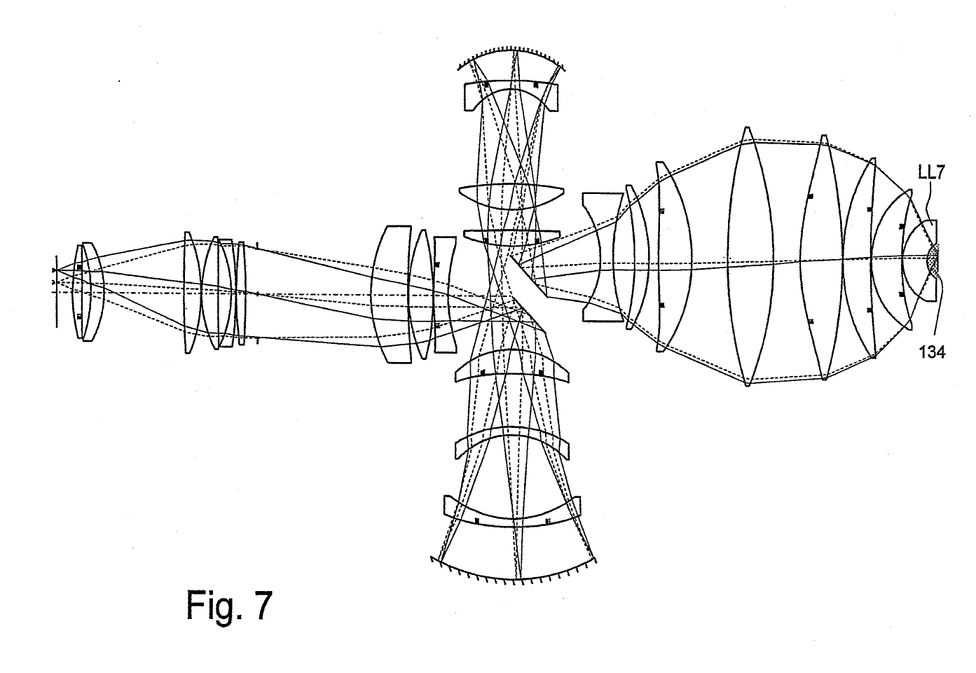

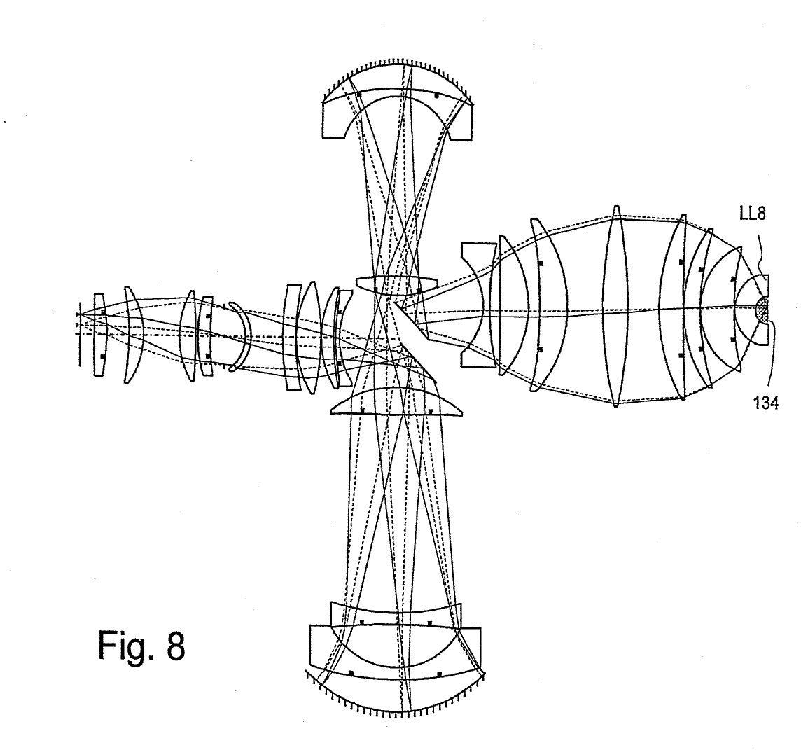

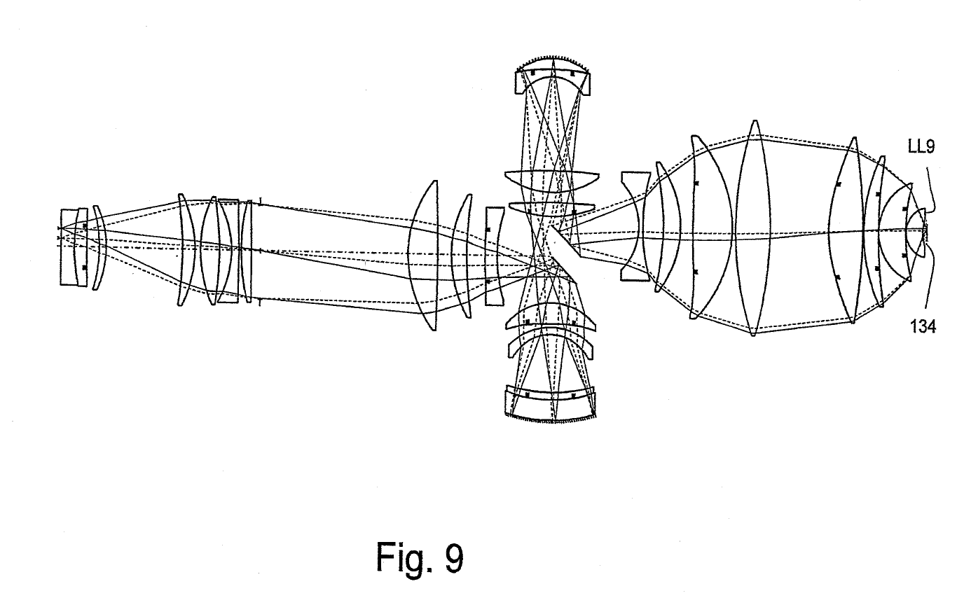

FIGS. 7 to 9 show meridian sections through three furthey exemplary embodiments of the projection objective 120 shown in FIGS. 1 and 2. The design data and aspherical constants of the projection objective shown in FIG. 7 are listed in Tables 3 and 4; Tables 5, 6 and Tables 7, 8 list the design data and aspherical constants for the embodiments shown in FIGS. 8 and 9, respectively.

The projection objectives shown in FIGS. 7 to 9 all have an image-side numerical aperture NA=1.40 and an immersion liquid with a refractive index of n_{L}=1.60. Thus this refractive index is always greater than the refractive index of the last lens element made of CaF₂, i.e. n_{L}>n_{CaF2}.

The projection objective shown in FIG. 7, which is designed for a wavelength λ=193 nm, is non-achromatized and has a last lens element LL7 with a strongly concavely curved image-side surface that forms a kind of cavity for the immersion liquid 134. The wavefront is corrected to about 2/100λ.

The projection objective shown in FIG. 8 is designed for a wavelength λ=157 nm and is achromatized. The image-side surface of the last lens element LL8 is even stronger concavely curved; apart from that, the radius of curvature is almost identical with the axial distance between the last lens element LL8 and the image plane, i.e. the center of curvature lies substantially within the image plane. As a result, the immersion liquid 134 has a large maximum thickness. Although the refractive index of CaF₂ is about n_{CaF2}=1.56 at λ=157 nm, the refractive index of the immersion liquid is still assumed to be larger (n_{L}=1.60). The wavefront is corrected to about 4/100λ.

The projection objective shown in FIG. 9 is designed for a wavelength λ=193 nm and is non-achromatized. The image-side surface of the last lens element LL9 has only a small concave curvature so that the immersion liquid 934 forms almost a flat layer. The radius of curvature is significantly (about a factor 10) greater than the axial distance between the last lens element LL9 and the image plane, i.e. there is a substantial distance between the center of curvature and the image plane. The maximum angel of incidence at the interface between the last lens element LL9 and the immersion liquid 934 is about 67° (i.e. sin α=0.92). The wavefront is corrected to about 5/100λ.

When comparing the wavefront errors in the similar embodiments shown in FIGS. 7 and 9, it becomes clear that the design of FIG. 7 with its greater curvature of the image-side surface of the last lens element LL7 allows to achieve a much better wavefront correction (2/100λ vs. 5/100λ). However, although the projection objective shown in FIG. 9 is not as well corrected as the projection objective shown in FIG. 7, due to the comparatively large radius of curvature there is only a small cavity underneath the last lens element LL9 which is advantageous for the reasons that have been mentioned above.

It goes without saying that the present invention is not restricted to the use in catadioptric projection objectives as have been described above. The invention can also advantageously be used in projection objectives having a smaller or larger number of intermediate images than in the embodiments shown, and also in dioptric projection objectives with or without any intermediate images. In addition, the optical axis may also extend through the center of the image field. Examples of further suitable lens designs are to be found, for example, in US 2002/0196533 A1, WO 01/050171 A1, WO 02/093209 A2 and U.S. Pat. No. 6,496,306A.

TABLE 1
Design data

| SURFACE | RADIUS | ASPHERICAL | THICKNESS | MATERIAL |
|---|---|---|---|---|
| Object plane | ∞ | | 37.648 | |
| 1 | 210.931 | | 21.995 | SiO₂ |
| 2 | 909.02 | | 1.605 | |
| 3 | 673.572 | | 22.728 | SiO₂ |
| 4 | −338.735 | x | 33.19 | |
| 5 | 130.215 | x | 8.994 | SiO₂ |
| 6 | 119.808 | | 36.001 | |
| 7 | 216 | | 40.356 | SiO₂ |
| 8 | −210.59 | | 0.939 | |
| 9 | 97.24 | | 49.504 | SiO₂ |
| 10 | 216.208 | x | 8.164 | |
| 12 | −65.704 | | 49.734 | SiO₂ |
| Diaphragm | ∞ | | 49.302 | |
| 13 | −113.325 | | 55.26 | |
| 14 | −6210.149 | x | 70.31 | SiO₂ |
| 15 | −195.536 | | 0.962 | |
| 16 | 3980.16 | | 65.997 | SiO₂ |
| 17 | −473.059 | | 277.072 | |
| 18 | −225.942 | x | 246.731 | Mirror |
| 19 | 193.745 | x | 294.329 | Mirror |
| 20 | −338.56 | x | 17.389 | SiO₂ |
| 21 | −206.244 | | 8.884 | |
| 22 | −148.97 | | 34.064 | SiO₂ |
| 23 | 129.921 | x | 40.529 | |
| 24 | −2704.885 | | 33.192 | SiO₂ |
| 25 | −195.599 | | 0.946 | |
| 26 | −794.214 | x | 30.169 | SiO₂ |
| 27 | −479.39 | | 24.236 | |
| 28 | −311.778 | x | 100.056 | SiO₂ |
| 29 | −159.333 | | 28.806 | |
| 30 | 309.839 | | 43.609 | SiO₂ |
| 31 | 836.077 | x | 0.951 | |
| 32 | 225.096 | | 55.667 | SiO₂ |
| 33 | 687.556 | | 0.945 | |
| 34 | 154.575 | | 64.278 | SiO₂ |
| 35 | 911.8 | x | 0.932 | |
| 36 | 89.986 | | 44.143 | SiO₂ |
| 37 | 199.475 | x | 0.878 | |
| 38 | 61.984 | | 9.635 | SiO₂ |
| 39 | 35.475 | | 34.43 | Liquid |
| 40 | ∞ | | | Resist |

TABLE 2
Aspherical constants

| Surface 4 | | Surface 5 | | Surface10 | | Surface 14 | |
|---|---|---|---|---|---|---|---|
| A | 5.36225288E−08 | A | 2.53854010E−08 | A | 4.51137087E−07 | A | −8.48905023E−09 |
| B | −5.17992581E−12 | B | −1.22713179E−11 | B | 2.46833840E−11 | B | 1.45061822E−13 |
| C | 8.49599769E−16 | C | 1.21417341E−15 | C | 5.78496960E−15 | C | −6.34351367E−18 |
| D | −7.57832730E−20 | D | −1.92474180E−19 | D | −4.39101683E−18 | D | 2.84301572E−22 |
| E | 3.59228710E−24 | E | 2.08240691E−23 | E | −5.64853356E−22 | E | −8.24902650E−27 |
| F | −9.16722201E−29 | F | −9.29539601E−28 | F | 4.95744749E−26 | F | 1.27798308E−31 |

| Surface 18 | | Surface 19 | | Surface 20 | |
|---|---|---|---|---|---|
| A | 1.04673033E−08 | A | −4.11099367E−09 | A | 1.14749646E−07 |
| B | 1.34351117E−13 | B | −9.91828838E−14 | B | −8.19248307E−12 |
| C | 1.03389626E−18 | C | −7.93614779E−19 | C | 8.78420843E−16 |
| D | 5.16847878E−23 | D | −1.66363646E−22 | D | −1.39638210E−19 |
| E | −1.23928686E−27 | E | 5.56486530E−27 | E | 2.09064504E−23 |
| F | 3.09904827E−32 | F | −1.79683490E−31 | F | −2.15981914E−27 |
| Surface 23 | | Surface 26 | | Surface 28 | |
| A | −2.87603531E−08 | A | −4.35420789E−08 | A | −2.70754285E−08 |
| B | −9.68432739E−12 | B | −6.70429494E−13 | B | −1.36708653E−12 |
| C | 6.88099059E−16 | C | −4.05835225E−17 | C | −2.46085956E−17 |
| D | −8.70009838E−20 | D | −1.10658303E−20 | D | 2.26651081E−21 |
| E | 9.59884320E−24 | E | 4.80978147E−25 | E | −1.20009586E−25 |
| F | −5.07639229E−28 | F | −5.35014389E−29 | F | 9.28622501E−30 |

| Surface 31 | | Surface 35 | | Surface 37 | |
|---|---|---|---|---|---|
| A | 4.38707762E−09 | A | 1.73743303E−08 | A | 1.04975421E−07 |
| B | −3.69893805E−13 | B | 1.60994523E−12 | B | 1.94141448E−11 |
| C | −4.93747026E−18 | C | −1.71036162E−16 | C | −2.31145732E−15 |
| D | 4.05461849E−22 | D | 1.26964535E−20 | D | 4.57201996E−19 |
| E | −7.59674606E−27 | E | −5.77497378E−25 | E | −3.92356845E−23 |
| F | 5.58403314E−32 | F | 1.55390733E−29 | F | 2.35233647E−27 |
| | | G | −1.78430224E−34 | | |

TABLE 3
Design data

| SUR- | | THICK- | MATE- | | |
|---|---|---|---|---|---|
| FACE | RADIUS | NESS | RIAL | INDEX | SEMIDIAM |
| 0 | ∞ | 32.0000 | | | 65.50 |
| 1 | ∞ | 0.0000 | | | 80.45 |
| 2 | 332.4480 | 18.9959 | SiO₂ | 1.560318 | 84.22 |
| 3 | 27083.8930 | 17.5539 | | | 85.42 |
| 4 | −253.5666 | 26.7129 | SiO₂ | 1.560318 | 86.06 |
| 5 | −179.3607 | 164.1318 | | | 90.72 |
| 6 | 1920.0084 | 34.5089 | SiO₂ | 1.560318 | 111.13 |
| 7 | −279.4103 | 0.9461 | | | 111.59 |
| 8 | 213.6767 | 34.3917 | SiO₂ | 1.560318 | 103.48 |
| 9 | 17137.3629 | 26.7484 | | | 100.67 |
| 10 | −208.9766 | 9.4997 | SiO₂ | 1.560318 | 99.22 |
| 11 | −609.1513 | 0.9500 | | | 97.67 |
| 12 | 734.0560 | 18.8742 | SiO₂ | 1.560318 | 95.00 |
| 13 | −1380.9253 | 24.2008 | | | 93.32 |
| 14 | ∞ | 231.0887 | | | 81.98 |
| 15 | 252.7510 | 74.6720 | SiO₂ | 1.560318 | 126.43 |
| 16 | 1098.5274 | 0.9492 | | | 121.38 |
| 17 | 268.9906 | 50.1845 | SiO₂ | 1.560318 | 119.28 |
| 18 | −463.5300 | 1.0915 | | | 117.08 |
| 19 | 697.8278 | 30.0054 | SiO₂ | 1.560318 | 106.59 |
| 20 | 292.0140 | 120.0163 | | | 94.90 |
| 21 | ∞ | 9.9914 | | | 82.23 |
| 22 | ∞ | −100.0083 | Mirror | 1.560318 | 142.10 |
| 23 | −178.0803 | −45.0048 | SiO₂ | 1.560318 | 115.52 |
| 24 | −663.9291 | −95.3149 | | | 113.38 |
| 25 | −237.9404 | −15.0000 | SiO₂ | 1.560318 | 115.72 |
| 26 | −166.3412 | −152.4364 | | | 111.11 |
| 27 | 222.8026 | −15.0000 | SiO₂ | 1.560318 | 127.22 |
| 28 | 539.8416 | −94.3687 | | | 138.91 |
| 29 | 364.8709 | 94.3687 | Mirror | | 167.04 |
| 30 | 539.8416 | 15.0000 | SiO₂ | 1.560318 | 138.91 |
| 31 | 222.8026 | 152.4364 | | | 127.22 |
| 32 | −166.3412 | 15.0000 | SiO₂ | 1.560318 | 111.11 |
| 33 | −237.9404 | 95.3149 | | | 115.72 |
| 34 | −663.9291 | 45.0048 | SiO₂ | 1.560318 | 113.38 |
| 35 | −178.0803 | 100.0083 | | | 115.52 |
| 36 | ∞ | 94.5942 | | | 122.31 |
| 37 | ∞ | −23.8903 | | | 91.10 |
| 38 | ∞ | 20.0000 | | | 179.89 |
| 39 | 254.8239 | 29.5175 | SiO₂ | 1.560318 | 96.82 |
| 40 | −2985.0549 | 36.7407 | | | 96.62 |
| 41 | 200.4128 | 45.9683 | SiO₂ | 1.560318 | 106.20 |
| 42 | −666.1976 | 170.5500 | | | 105.01 |
| 43 | −95.1516 | 15.0000 | SiO₂ | 1.560318 | 77.96 |
| 44 | −643.9252 | 55.6492 | | | 95.09 |
| 45 | −175.8508 | −55.6492 | Mirror | | 109.51 |
| 46 | −643.9252 | −15.0000 | SiO₂ | 1.560318 | 95.09 |
| 47 | −95.1516 | −170.5500 | | | 77.96 |
| 48 | −666.1976 | −45.9683 | SiO₂ | 1.560318 | 105.01 |
| 49 | 200.4128 | −12.1735 | | | 106.20 |
| 50 | ∞ | −24.5646 | | | 90.83 |
| 51 | −2985.0549 | −29.5175 | SiO₂ | 1.560318 | 96.62 |
| 52 | 254.8239 | −20.0000 | | | 96.82 |
| 53 | ∞ | 180.1673 | Mirror | | 134.73 |
| 54 | −148.5117 | 25.7491 | SiO₂ | 1.560318 | 95.86 |
| 55 | 327.9861 | 43.1843 | | | 116.84 |
| 56 | −496.1113 | 30.0070 | SiO₂ | 1.560318 | 124.28 |
| 57 | −252.6773 | 19.1777 | | | 130.89 |
| 58 | 1365.3904 | 68.1411 | SiO₂ | 1.560318 | 165.17 |
| 59 | −284.3746 | 73.5313 | | | 172.58 |
| 60 | 754.4880 | 93.5313 | SiO₂ | 1.560318 | 234.19 |
| 61 | −588.1067 | 54.2510 | | | 235.10 |
| 62 | 357.9132 | 85.3268 | SiO₂ | 1.560318 | 221.99 |
| 63 | −762.8649 | 0.9929 | | | 220.72 |
| 64 | 304.8598 | 57.6484 | SiO₂ | 1.560318 | 181.91 |
| 65 | 1098.9629 | 0.9340 | | | 177.48 |
| 66 | 143.0811 | 62.6047 | SiO₂ | 1.560318 | 127.33 |
| 67 | 347.6273 | 0.9010 | | | 177.47 |
| 68 | 79.6669 | 50.1800 | CaF₂ | 1.501403 | 73.25 |
| 69 | 36.1540 | 21.2194 | Liquid | 1.600000 | 31.82 |
| 70 | ∞ | | | | 19.38 |

TABLE 4
Aspherical constants

| SURFACE | 3 | 19 | 24 | 28 | 30 |
|---|---|---|---|---|---|
| K | 0 | 0 | 0 | 0 | 0 |
| A | 4.047232E−09 | −4.175853E−08 | −3.889430E−08 | 6.661869E−09 | 6.661869E−09 |
| B | 8.449241E−13 | −5.621416E−13 | 2.260825E−13 | 2.899240E−13 | 2.899240E−13 |
| C | 5.603175E−17 | −2.909466E−19 | 9.880822E−18 | −1.932302E−17 | −1.932302E−17 |
| D | −4.004583E−21 | 3.690043E−22 | −2.672567E−22 | 1.602360E−21 | 1.602360E−21 |
| E | −8.168767E−25 | 2.119217E−26 | 4.717688E−26 | −6.342246E−26 | −6.342246E−26 |
| F | 2.123279E−29 | −9.535588E−31 | −3.817055E−30 | 1.183564E−30 | 1.183564E−30 |
| SURFACE | 34 | 39 | 44 | 46 | 52 |
| K | 0 | 0 | 0 | 0 | 0 |
| A | −3.889430E−08 | −2.037803E−08 | −1.157857E−08 | −1.157857E−08 | −2.037803E−08 |
| B | 2.260825E−13 | −6.612137E−13 | 1.455623E−12 | 1.455623E−12 | −6.612137E−13 |
| C | 9.880822E−18 | 2.840028E−17 | −5.746524E−17 | −5.746524E−17 | 2.840028E−17 |
| D | −2.672567E−22 | −4.931922E−21 | 1.261354E−21 | 1.261354E−21 | −4.931922E−21 |
| E | 4.717688E−26 | 4.142905E−25 | 4.054615E−25 | 4.054615E−25 | 4.142905E−25 |
| F | −3.817055E−30 | −1.562251E−29 | −2.761361E−29 | −2.761361E−29 | −1.562251E−29 |

| SURFACE | 58 | 62 | 65 | 67 |
|---|---|---|---|---|
| K | 0 | 0 | 0 | 0 |
| A | −1.679180E−08 | −1.483428E−08 | −9.489171E−09 | −1.782977E−08 |
| B | −5.846864E−14 | −2.269457E−14 | 5.001612E−13 | 9.574096E−13 |
| C | 7.385649E−18 | 4.944523E−18 | −1.283531E−17 | 7.878477E−17 |
| D | −5.142028E−22 | −1.410026E−22 | −8.674473E−23 | −7.167182E−21 |
| E | 1.479187E−26 | 1.643655E−27 | 7.103644E−27 | 2.682224E−25 |
| F | −2.189903E−31 | −7.668842E−33 | −7.251904E−32 | −3.423260E−30 |

TABLE 5
Design data

| SUR- | | THICK- | MATE- | | |
|---|---|---|---|---|---|
| FACE | RADIUS | NESS | RIAL | INDEX | SEMIDIAM |
| 0 | ∞ | 32.0000 | | | 65.50 |
| 1 | ∞ | 0.0000 | | | 80.46 |
| 2 | 3568.5495 | 29.3610 | CAF₂ | 1.555560 | 80.77 |
| 3 | −306.4778 | 50.8080 | | | 84.99 |
| 4 | −495.7015 | 32.5298 | CAF₂ | 1.555560 | 97.37 |
| 5 | −161.1181 | 81.4155 | | | 99.50 |
| 6 | 188.0753 | 36.2525 | CAF₂ | 1.555560 | 93.00 |
| 7 | −1013.7352 | 6.1886 | | | 90.93 |
| 8 | 288.3482 | 26.9703 | CAF₂ | 1.555560 | 82.17 |
| 9 | 872.7887 | 32.5801 | | | 74.60 |
| 10 | ∞ | 47.8395 | | | 57.76 |
| 11 | −76.3176 | 12.9591 | CAF₂ | 1.555560 | 65.40 |
| 12 | −82.8195 | 72.8834 | | | 71.21 |
| 13 | 494.0581 | 30.0025 | CAF₂ | 1.555560 | 105.98 |
| 14 | 500.2689 | 0.9499 | | | 109.01 |
| 15 | 210.1705 | 55.9335 | CAF₂ | 1.555560 | 115.54 |
| 16 | −462.2471 | 0.9442 | | | 114.96 |
| 17 | 191.5029 | 28.1484 | CAF₂ | 1.555560 | 104.19 |
| 18 | 469.5739 | 3.8083 | | | 100.65 |
| 19 | 313.4359 | 9.4935 | CAF₂ | 1.555560 | 99.24 |
| 20 | 161.6230 | 115.1964 | | | 91.07 |
| 21 | ∞ | 14.7967 | | | 90.40 |
| 22 | ∞ | −100.0183 | Mirror | | 206.37 |
| 23 | −247.2670 | −56.5211 | CAF₂ | 1.555560 | 148.25 |
| 24 | 1546.1350 | −403.3917 | | | 147.84 |
| 25 | 500.0000 | −25.0000 | CAF₂ | 1.555560 | 142.88 |
| 26 | −2059.5717 | −87.3199 | | | 147.68 |
| 27 | 173.4701 | −25.0000 | CAF₂ | 1.555560 | 148.30 |
| 28 | 823.5657 | −65.7941 | | | 193.66 |
| 29 | 295.8639 | 65.7941 | Mirror | | 204.70 |
| 30 | 823.5657 | 25.0000 | CAF₂ | 1.555560 | 193.66 |
| 31 | 173.4701 | 87.3199 | | | 148.30 |
| 32 | −2059.5717 | 25.0000 | CAF₂ | 1.555560 | 147.68 |
| 33 | 500.0000 | 403.3917 | | | 142.88 |
| 34 | 1546.1350 | 56.5211 | CAF₂ | 1.555560 | 147.84 |
| 35 | −247.2670 | 100.0183 | | | 148.25 |
| 36 | ∞ | 49.8789 | | | 125.86 |
| 37 | ∞ | 20.8278 | | | 89.12 |
| 38 | ∞ | 20.0000 | | | 149.02 |
| 39 | 215.5222 | 38.8898 | CAF₂ | 1.555560 | 91.59 |
| 40 | −548.9606 | 360.6137 | | | 90.02 |
| 41 | −126.6780 | 15.0000 | CAF₂ | 1.555560 | 120.92 |
| 42 | −567.9480 | 48.8335 | | | 169.01 |
| 43 | −224.2817 | −48.8335 | Mirror | | 171.87 |
| 44 | −567.9480 | −15.0000 | CAF₂ | 1.555560 | 169.01 |
| 45 | −126.6780 | −314.8668 | | | 120.92 |
| 46 | ∞ | −45.7487 | | | 81.94 |
| 47 | −548.9606 | −38.8898 | CAF₂ | 1.555560 | 90.02 |
| 48 | 215.5222 | −20.0000 | | | 91.59 |
| 49 | ∞ | 195.8787 | Mirror | | 133.74 |
| 50 | −121.2718 | 15.1499 | CAF₂ | 1.555560 | 97.18 |
| 51 | 529.2614 | 24.3014 | | | 127.08 |
| 52 | −8438.5548 | 64.5537 | CAF₂ | 1.555560 | 137.42 |
| 53 | −202.6253 | 25.2464 | | | 142.97 |
| 54 | −1447.9251 | 63.0634 | CAF₂ | 1.555560 | 168.91 |
| 55 | −254.3816 | 80.5189 | | | 174.93 |
| 56 | 783.5550 | 57.0370 | CAF₂ | 1.555560 | 203.06 |
| 57 | −939.7625 | 70.4486 | | | 203.12 |
| 58 | 358.1334 | 55.4484 | CAF₂ | 1.555560 | 186.96 |
| 59 | 5861.2627 | 0.9614 | | | 184.33 |
| 60 | 259.9889 | 36.5173 | CAF₂ | 1.555560 | 161.62 |
| 61 | 371.5128 | 0.8975 | | | 156.47 |
| 62 | 134.7936 | 77.4909 | CAF₂ | 1.555560 | 127.53 |
| 63 | 767.8631 | 0.7967 | | | 119.07 |
| 64 | 72.9080 | 48.3195 | CAF₂ | 1.555560 | 70.97 |
| 65 | 29.7284 | 27.0563 | IMMO16 | 1.600000 | 31.25 |
| 66 | ∞ | | | | 19.39 |

TABLE 6
Aspherical constants

| SURFACE | 3 | 9 | 19 | 24 | 26 |
|---|---|---|---|---|---|
| K | 0 | 0 | 0 | 0 | 0 |
| A | 2.172737E−08 | 8.983641E−08 | −5.825972E−08 | −1.605889E−08 | −2.779244E−10 |
| B | 1.718631E−12 | −5.996759E−12 | −6.306762E−13 | 4.504977E−16 | −3.062909E−14 |
| C | 1.514127E−16 | 6.363808E−16 | −2.783920E−17 | 3.596627E−21 | 1.861506E−18 |
| D | −2.716770E−22 | −3.998733E−20 | −1.594705E−21 | 2.792862E−22 | −2.425072E−22 |
| E | −1.008203E−24 | −5.130142E−24 | 2.956685E−25 | −1.885291E−26 | 1.114443E−26 |
| F | −1.157181E−28 | 1.266998E−28 | −1.064251E−29 | 3.351694E−31 | −2.553147E−31 |

| SURFACE | 28 | 30 | 32 | 34 |
|---|---|---|---|---|
| K | 0 | 0 | 0 | 0 |
| A | 4.632690E−09 | 4.632690E−09 | −2.779244E−10 | −1.605889E−08 |
| B | −3.213384E−14 | −3.213384E−14 | −3.062909E−14 | 4.504977E−16 |
| C | 7.229632E−20 | 7.229632E−20 | 1.861506E−18 | 3.596627E−21 |
| D | 2.100335E−23 | 2.100335E−23 | −2.425072E−22 | 2.792862E−22 |
| E | −5.592560E−28 | −5.592560E−28 | 1.114443E−26 | −1.885291E−26 |
| F | 6.249291E−33 | 6.249291E−33 | −2.553147E−31 | 3.351694E−31 |
| SURFACE | 39 | 42 | 44 | 48 |
| K | 0 | 0 | 0 | 0 |
| A | −1.815667E−08 | −9.514646E−09 | −9.514646E−09 | −1.815667E−08 |
| B | −2.488991E−13 | 1.336864E−13 | 1.336864E−13 | −2.488991E−13 |
| C | 2.824306E−17 | −4.722253E−18 | −4.722253E−18 | 2.824306E−17 |
| D | −4.697303E−21 | 1.120165E−22 | 1.120165E−22 | −4.697303E−21 |
| E | 3.415362E−25 | −1.895395E−27 | −1.895395E−27 | 3.415362E−25 |
| F | −9.509214E−30 | 1.489410E−32 | 1.489410E−32 | −9.509214E−30 |

| SURFACE | 54 | 59 | 61 | 63 |
|---|---|---|---|---|
| K | 0 | 0 | 0 | 0 |
| A | −1.031964E−08 | 8.72E−09 | −2.45E−08 | 4.37E−08 |
| B | −1.081794E−13 | −2.71E−13 | 6.62E−13 | −8.96E−13 |
| C | 6.909628E−18 | 1.07E−17 | −1.32E−17 | 4.21E−17 |
| D | −3.648077E−22 | −6.07E−22 | 6.68E−22 | −3.88E−21 |
| E | 9.693996E−27 | 1.40E−26 | −1.47E−26 | 2.01E−25 |
| F | −1.380442E−31 | −1.10E−31 | 1.14E−31 | −3.84E−30 |

TABLE 7
Design data

| SUR- | | THICK- | MATE- | | |
|---|---|---|---|---|---|
| FACE | RADIUS | NESS | RIAL | INDEX | SEMIDIAM. |
| 0 | ∞ | 32.0000 | | | 65.50 |
| 1 | ∞ | 0.0000 | | | 80.45 |
| 2 | 361.5503 | 30.0063 | SiO₂ | 1.560318 | 83.87 |
| 3 | 3766.1854 | 29.9775 | | | 86.87 |
| 4 | −313.0243 | 17.3177 | SiO₂ | 1.560318 | 90.72 |
| 5 | −211.2930 | 182.7697 | | | 93.19 |
| 6 | −709.0001 | 29.1631 | SiO₂ | 1.560318 | 120.83 |
| 7 | −255.7121 | 13.1321 | | | 122.28 |
| 8 | 261.1325 | 45.4463 | SiO₂ | 1.560318 | 118.65 |
| 9 | −728.3260 | 29.9790 | | | 116.70 |
| 10 | −209.1405 | 18.3161 | SiO₂ | 1.560318 | 113.35 |
| 11 | −2675.8307 | 4.7872 | | | 113.10 |
| 12 | 421.7508 | 25.2987 | SiO₂ | 1.560318 | 112.42 |
| 13 | −5576.5014 | 21.4392 | | | 111.29 |
| 14 | ∞ | 355.5491 | | | 103.93 |
| 15 | 249.8044 | 71.3667 | SiO₂ | 1.560318 | 163.42 |
| 16 | −4441.8089 | 32.5158 | | | 161.31 |
| 17 | 247.2422 | 37.4261 | SiO₂ | 1.560318 | 135.08 |
| 18 | 797.4045 | 43.7199 | | | 130.81 |
| 19 | 665.9047 | 30.0078 | SiO₂ | 1.560318 | 108.60 |
| 20 | 318.3673 | 120.0233 | | | 96.83 |
| 21 | ∞ | 9.9881 | | | 79.40 |
| 22 | ∞ | −100.0079 | Mirror | | 122.85 |
| 23 | −145.3105 | −45.0039 | SiO₂ | 1.560318 | 107.21 |
| 24 | −705.3999 | −7.6524 | | | 104.90 |
| 25 | −149.2286 | −15.0000 | SiO₂ | 1.560318 | 100.69 |
| 26 | −107.5358 | −125.6003 | | | 91.50 |
| 27 | 398.2665 | −15.0000 | SiO₂ | 1.560318 | 101.84 |
| 28 | 419.3212 | −44.0802 | | | 104.16 |
| 29 | 398.6744 | 44.0802 | Mirror | | 107.66 |
| 30 | 419.3212 | 15.0000 | SiO₂ | 1.560318 | 104.16 |
| 31 | 398.2665 | 125.6003 | | | 101.84 |
| 32 | −107.5358 | 15.0000 | SiO₂ | 1.560318 | 91.50 |
| 33 | −149.2286 | 7.6524 | | | 100.69 |
| 34 | −705.3999 | 45.0039 | SiO₂ | 1.560318 | 104.90 |
| 35 | −145.3105 | 100.0079 | | | 107.21 |
| 36 | ∞ | 103.9571 | | | 130.84 |
| 37 | ∞ | −33.2893 | | | 99.43 |
| 38 | ∞ | 20.0000 | | | 210.81 |
| 39 | 250.9147 | 31.5356 | SiO₂ | 1.560318 | 101.23 |
| 40 | −1057.0829 | 21.3930 | | | 102.52 |
| 41 | 202.0288 | 47.3927 | SiO₂ | 1.560318 | 111.71 |
| 42 | −941.7186 | 197.8094 | | | 110.48 |
| 43 | −88.9067 | 15.0000 | SiO₂ | 1.560318 | 72.67 |
| 44 | −573.5619 | 23.1569 | | | 88.88 |
| 45 | −142.4338 | −23.1569 | Mirror | | 89.38 |
| 46 | −573.5619 | −15.0000 | SiO₂ | 1.560318 | 88.88 |
| 47 | −88.9067 | −197.8094 | | | 72.67 |
| 48 | −941.7186 | −47.3927 | SiO₂ | 1.560318 | 110.48 |
| 49 | 202.0288 | −11.3868 | | | 111.71 |
| 50 | ∞ | −9.9896 | | | 92.32 |
| 51 | −1057.0829 | −31.5356 | SiO₂ | 1.560318 | 102.52 |
| 52 | 250.9147 | −20.0000 | | | 101.23 |
| 53 | ∞ | 209.4519 | Mirror | | 135.07 |
| 54 | −133.90811 | 9.4987 | SiO₂ | 1.560318 | 97.71 |
| 55 | 406.9979 | 48.9711 | | | 119.82 |
| 56 | −523.9173 | 41.1332 | SiO₂ | 1.560318 | 135.89 |
| 57 | −224.0541 | 29.8664 | | | 142.55 |
| 58 | 1367.6570 | 94.8234 | SiO₂ | 1.560318 | 191.42 |
| 59 | −271.7647 | 8.1788 | | | 198.87 |
| 60 | 667.9279 | 83.6854 | SiO₂ | 1.560318 | 232.81 |
| 61 | −808.5395 | 140.7841 | | | 233.01 |
| 62 | 286.6775 | 82.6895 | SiO₂ | 1.560318 | 201.18 |
| 63 | −1096.4782 | 0.9668 | | | 198.76 |
| 64 | 350.5350 | 35.6242 | SiO₂ | 1.560318 | 164.87 |
| 65 | 884.2685 | 0.9173 | | | 159.58 |
| 66 | 115.9293 | 64.9068 | SiO₂ | 1.560318 | 108.97 |
| 67 | 412.6826 | 0.8041 | | | 99.04 |
| 68 | 57.1792 | 41.0408 | CaF₂ | 1.501403 | 55.06 |
| 69 | 99.9106 | 10.1713 | Liquid | 1.600000 | 30.68 |
| 70 | ∞ | | | | 19.40 |

TABLE 8
Aspherical constants

| SURFACE | 3 | 19 | 24 | 28 | 30 |
|---|---|---|---|---|---|
| K | 0 | 0 | 0 | 0 | 0 |
| A | −1.001534E−09 | −4.128786E−08 | −4.510495E−08 | 1.339665E−08 | 1.339665E−08 |
| B | 6.144615E−13 | −4.980750E−13 | 6.742821E−13 | 1.482582E−12 | 1.482582E−12 |
| C | 1.247768E−16 | 2.649167E−18 | 3.004246E−17 | −1.857530E−16 | −1.857530E−16 |
| D | −1.048854E−20 | 5.315992E−22 | 2.453737E−21 | 3.433994E−20 | 3.433994E−20 |
| E | −4.463818E−25 | −6.165935E−27 | −3.687563E−25 | −2.905941E−24 | −2.905941E−24 |
| F | 6.154983E−30 | 1.945950E−32 | −1.491146E−30 | 1.237374E−28 | 1.237374E−28 |
| SURFACE | 34 | 39 | 44 | 46 | 52 |
| K | 0 | 0 | 0 | 0 | 0 |
| A | −4.510495E−08 | −2.582589E−08 | −1.589920E−08 | −1.589920E−08 | −2.582589E−08 |
| B | 6.742821E−13 | −4.336537E−13 | 1.112204E−12 | 1.112204E−12 | −4.336537E−13 |
| C | 3.004246E−17 | 5.153775E−17 | −2.537422E−17 | −2.537422E−17 | 5.153775E−17 |
| D | 2.453737E−21 | −7.829187E−21 | −5.148293E−21 | −5.148293E−21 | −7.829187E−21 |
| E | −3.687563E−25 | 5.696031E−25 | 8.322199E−25 | 8.322199E−25 | 5.696031E−25 |
| F | −1.491146E−30 | −1.711252E−29 | −2.485886E−29 | −2.485886E−29 | −1.711252E−29 |

| SURFACE | 58 | 62 | 65 | 67 |
|---|---|---|---|---|
| K | 0 | 0 | 0 | 0 |
| A | −1.313863E−08 | −1.809441E−08 | −1.821041E−09 | −4.599046E−10 |
| B | 1.817234E−14 | −2.428724E−14 | 4.495016E−13 | 3.983791E−12 |
| C | 2.355838E−18 | 1.168088E−17 | −7.637258E−18 | −1.382332E−16 |
| D | −1.447425E−22 | −4.545469E−22 | −1.610477E−21 | −2.858839E−21 |
| E | 3.333235E−22 | 7.354258E−27 | 7.379400E−26 | 4.614539E−25 |
| F | −4.355238E−32 | −4.766510E−32 | −9.483899E−31 | −1.411510E−29 |

1. A projection objective configured to image an object in an object plane of the projection objective onto an image plane of the projection objective, the projection objective comprising:
an optical element that is the last optical element of the projection objective on the image side; and
an immersion liquid adjoining the image plane of the projection objective,
wherein:
the immersion liquid is convexly curved towards the object plane;
the optical element has a concavely curved image-side surface directly adjoining the immersion liquid;
a refractive index of the immersion liquid is greater than a refractive index of the optical element;
a maximum curvature of the concavely curved image-side surface of the optical element has a radius of curvature that equals a product m·s;
s is an axial distance between the concavely curved image-side surface of the optical element and the image plane;
m is a real number between 20 and 120; and
the projection objective is a microlithography projection objective.

2. The projection objective according to claim 1, wherein the concavely curved image-side surface of the optical element is surrounded by a drainage barrier.

3. The projection objective according to claim 2, wherein the drainage barrier comprises a ring joined to the optical element and/or to a housing of the projection objective.

4. The projection objective according to claim 1, wherein the concavely curved image-side surface of the optical element is spherical.

5. The projection objective according to claim 4, wherein the concavely curved image-side surface of the optical element has a radius of curvature that is between 0.9 times and 1.5 times the axial distance between the concavely curved image-side surface of the optical element and the image plane.

6. The projection objective according to claim 1, further comprising:
an intermediate liquid; and
an optical element that is the last optical element of the projection objective on the image side,
wherein:
the intermediate liquid is between the immersion liquid and the optical element that is the last optical element of the projection objective on the image side;
the intermediate liquid is not miscible with the immersion liquid; and
the intermediate liquid forms a curved interface in an electric field.

7. The projection objective according to claim 6, wherein the intermediate liquid is electrically conductive, and the immersion liquid is electrically insulating.

8. The projection objective according to claim 6, wherein the intermediate liquid has substantially the same density as the immersion liquid.

9. The projection objective according to claim 8, wherein the immersion liquid is an oil, and the intermediate liquid is water.

10. The projection objective according to claim 6, further comprising an electrode configured to generate the electric field.

11. The projection objective according to claim 10, wherein the electrode is an annular conical electrode that is disposed between the image plane and the optical element that is the last optical element of the projection objective on the image side.

12. The projection objective according to claim 10, wherein a curvature of the curved interface of the intermediate liquid can be altered by altering a voltage applied to the electrode.

13. The projection objective according to claim 6, wherein the interface between the intermediate liquid and the immersion liquid is at least approximately spherical.

14. The projection objective according to claim 1, wherein the immersion liquid forms an interface with the optical element that is convexly curved towards the object plane so that, during use of the projection objective, light rays pass the interface with a maximum angle of incidence whose sine is between 0.5 and 0.98.

15. The projection objective according to claim 14, wherein the sine of the maximum angle of incidence is between 0.85 and 0.95.

16. The projection objective according to claim 14, wherein the sine of the maximum angle of incidence is between 0.87 and 0.94.

17. The projection objective according to claim 1, wherein within any arbitrary volume within the projection objection the condition (k²+l²)/n²<0.95 holds, wherein k, l, m are the three direction cosines of an aperture ray, n is the refractive index within the volume with k²+l²+m²=n².

18. The projection objective according to claim 1, wherein within any arbitrary volume within the projection objection the condition (k²+l²)/n²<0.85 holds, wherein k, l, m are the three direction cosines of an aperture ray, n is the refractive index within the volume with k²+l²+m²=n².

19. The projection objective according to claim 1, wherein m is between 40 and 100.

20. The projection objective according to claim 1, wherein m is between 70 and 90.

21. The projection objective according to claim 1, wherein the optical element comprises quartz glass.

22. The projection objective according to claim 1, wherein the projection objective is a catadioptric objective comprising at least two imaging mirrors, and the projection objective forms at least two intermediate images during use of the projection objective.

23. A microlithographic projection exposure apparatus comprising the projection objective according to claim 22.

24. A projection objective configured to image an object in an object plane of the projection objective onto an image plane of the projection objective, the projection objective comprising:
an immersion liquid adjoining the image plane of the projection objective; and
a medium forming an interface with the immersion liquid on the object side of the medium,
wherein:
the interface is convexly curved towards the object plane;
the interface has a maximum radius of curvature that equals the product m·s;
s is an axial distance between the interface and the image plane;
m is a real number between 20 and 120; and
the projection objective is a microlithography projection objective.

25. The projection objective according to claim 24, wherein m is between 40 and 100.

26. The projection objective according to claim 24, wherein m is between 70 and 90.

27. A method, comprising:
a) providing a substrate to which a layer of a photosensitive material is at least partially applied;
b) providing a mask that contains structures to be imaged;
c) providing a projection exposure apparatus comprising a projection objective; according to claim 1; and
d) projecting at least a part of the mask on a region of the layer with the aid of the projection exposure apparatus,
wherein the method produces microstructured components.

28. A method, comprising:
a) providing a substrate to which a layer of a photosensitive material is at least partially applied;
b) providing a mask that contains structures to be imaged;
c) providing a projection exposure apparatus comprising a projection objective according to claim 24; and
d) projecting at least a part of the mask on a region of the layer with the aid of the projection exposure apparatus,
wherein the method produces microstructured components.
